(19) United States
(12) Patent Application Publication
(10) Pub. No.: US 2024/0164192 A1
(43) Pub. Date: May 16, 2024

(54) DISPLAY MODULE AND DISPLAY DEVICE

(71) Applicant: BOE TECHNOLOGY GROUP CO., LTD., Beijing (CN)

(72) Inventors: Xueyan TIAN, Beijing (CN); Chunyang WANG, Beijing (CN)

(73) Assignee: BOE TECHNOLOGY GROUP CO., LTD., Beijing (CN)

(21) Appl. No.: 17/780,832

(22) PCT Filed: Mar. 31, 2021
(86) PCT No.: PCT/CN2021/084507

§ 371 Date: May 27, 2022

(51) Int. Cl. H10K 59/80

(52) U.S. Cl. CPC H10K 59/8791

(57) ABSTRACT

A display module includes a display panel and an anti-glare substrate. The display panel has a light exit surface and a backlight surface. The anti-glare substrate is disposed on a side of the light exit surface of the display panel. The anti-glare substrate includes a base, a first laminated structure and a second laminated structure. The first laminated structure and the second laminated structure are disposed on opposite sides of the base. A plurality of high-refractive-index film layers and at least one low-refractive-index film layer included in the first laminated structure are alternately arranged on a side of the base. A plurality of high-refractive-index film layers and at least one low-refractive-index film layer included in the second laminated structure are alternately arranged on another side of the base. In the first laminated structure and the second laminated structure, a film layer farthest from the base is a high-refractive-index film layer.

### CROSS-REFERENCE TO RELATED APPLICATION

This application is a national phase entry under 35 USC 371 of International Patent Application No. PCT/CN2021/084507, filed on Mar. 31, 2021, which is incorporated herein by reference in its entirety.

### TECHNICAL FIELD

The present disclosure relates to the field of display technologies, and in particular, to a display module and a display device.

### BACKGROUND

Vehicles (such as cars and trucks) each include rearview mirrors and vehicle lights, and the rearview mirrors include an interior rearview mirror (head-up rearview mirror) disposed inside the vehicle and exterior rearview mirrors disposed outside the vehicle. In some vehicles, the interior rearview mirror is a vehicle rearview mirror display with a display function (vehicular rearview display). In a normal driving state of the vehicle, the vehicle rearview mirror display may be used as a reflecting mirror, which is convenient for the driver to observe road condition information behind the vehicle. In a reversing state, the vehicle rearview mirror display connected to a reversing image system is used as a display to display road condition information behind the vehicle, which assists the driver in reversing and parking. The vehicle rearview mirror display may be a liquid crystal display (LCD) or an organic light-emitting diode (OLED) display.

During driving of the vehicle at night, vehicle lights are turned on to ensure the driver's vision. However, if there are other vehicle(s) driving in a same direction behind the vehicle, and vehicle lights, especially high beams, of the other vehicle(s) are turned on, light from the rear vehicle will be reflected into the driver's eyes of the front vehicle through rearview mirrors of the front vehicle. As a result, the driver of the front vehicle is dazzled, which affects driving safety of the front vehicle and increases safety risks of driving.

Therefore, on a premise of ensuring a minimum reflectance of the vehicle rearview mirror display (ensuring that the driver can observe road conditions behind the vehicle during the day), it is difficult for the design of the vehicle rearview mirror display to reduce an influence of light from the rear vehicle on the driver, so as to ensure driving safety of the driver at night.

### SUMMARY

In one aspect, a display module is provided. The display panel includes a display panel and an anti-glare substrate. The display panel has a light exit surface and a backlight surface. The anti-glare substrate is disposed on a side of the light exit surface of the display panel. The anti-glare substrate includes a base, a first laminated structure and a second laminated structure. The first laminated structure and the second laminated structure are respectively disposed on opposite sides of the base. The first laminated structure includes a plurality of high-refractive-index film layers and at least one low-refractive-index film layer, and the plurality of high-refractive-index film layers and the at least one low-refractive-index film layer included in the first laminated structure are alternately arranged on a side of the base. The second laminated structure includes a plurality of high-refractive-index film layers and at least one low-refractive-index film layer, and the plurality of high-refractive-index film layers and the at least one low-refractive-index film layer included in the second laminated structure are alternately arranged on another side of the base. In the first laminated structure, a film layer farthest from the base and a film layer closest to the base are both high-refractive-index film layers. In the second laminated structure, a film layer farthest from the base and a film layer closest to the base are both high-refractive-index film layers.

In some embodiments, the number of film layers of the first laminated structure and the number of film layers of the second laminated structure are the same.

In some embodiments, a thickness of a high-refractive-index film layer of the first laminated structure and a thickness of a high-refractive-index film layer of the second laminated structure are in a range from 10 nm to 45 nm; and/or a thickness of a low-refractive-index film layer of the first laminated structure and a thickness of a low-refractive-index film layer of the second laminated structure are in a range from 80 nm to 120 nm.

In some embodiments, a refractive index of a high-refractive-index film layer of the first laminated structure to visible light and a refractive index of a high-refractive-index film layer of the second laminated structure to visible light are in a range from 2 to 2.5, and/or a refractive index of a low-refractive-index film layer of the first laminated structure to visible light and a refractive index of a low-refractive-index film layer of the second laminated structure to visible light are in a range from 1.3 to 1.5.

In some embodiments, a material of a high-refractive-index film layer of the first laminated structure and a material of a high-refractive-index film layer of the second laminated structure include one or more of titanium dioxide, niobium pentoxide and tantalum pentoxide; and/or a material of a low-refractive-index film layer of the first laminated structure and a material of a low-refractive-index film layer of the second laminated structure include silicon dioxide and/or magnesium fluoride.

In some embodiments, the first laminated structure and the second laminated structure each include three film layers; the three film layers are sequentially a first high-refractive-index film layer, a first low-refractive-index film layer and a second high-refractive-index film layer in a direction perpendicular to and away from the base.

In some embodiments, a ratio of a thickness of the first high-refractive-index film layer to a thickness of the second high-refractive-index film layer is in a range from 2/7 to 4/7; and a ratio of the thickness of the first high-refractive-index film layer to a thickness of the first low-refractive-index film layer is in a range from 1/10 to 1/5.

In some embodiments, the first high-refractive-index film layer is made of titanium dioxide, and a thickness thereof is in a range from 13 nm to 17 nm; and the first low-refractive-index film layer is made of silicon dioxide, and a thickness thereof is in a range from 98 nm to 102 nm; and the second high-refractive-index film layer is made of titanium dioxide, and a thickness thereof is in a range from 33 nm to 37 nm.

In another aspect, a display module is provided. The display module includes a display panel and an anti-glare substrate. The display panel has a light exit surface and a backlight surface. The anti-glare substrate is disposed on a side of the light exit surface of the display panel. The anti-glare substrate includes a base and two laminated structures that are respectively disposed on opposite sides of the base. Each laminated structure includes a plurality of high-refractive-index film layers and at least one low-refractive-index film layer. The plurality of high-refractive-index film layers and the at least one low-refractive-index film layer are alternately arranged on the base. In the laminated structure, a film layer farthest from the base and a film layer closest to the base are both high-refractive-index film layers. A thickness of each high-refractive-index film layer is in a range from 10 nm to 45 nm, and a refractive index of the high-refractive-index film layer to visible light is in a range from 2 to 2.5, and/or a thickness of each low-refractive-index film layer is in a range from 80 nm to 120 nm, and a refractive index of the low-refractive-index film layer to visible light is in a range from 1.3 to 1.5.

In another aspect, a display device is provided. The display device includes the display module described in any one of the above embodiments.

In some embodiments, the display device further includes a circular polarizer and an optical adhesive. The circular polarizer is disposed between the display panel and the anti-glare substrate of the display module, and the optical adhesive is disposed between the circular polarizer and the anti-glare substrate to bond the circular polarizer to the anti-glare substrate.

In some embodiments, the display device further includes an adhesive layer disposed between the display panel and the circular polarizer to bond the display panel to the circular polarizer.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art can obtain other drawings according to these accompanying drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a sectional view of the display device in FIG. 1 taken along line A-A;

FIG. 3 is a reflectance curve diagram of an anti-glare substrate to light in specific wavelengths, in accordance with some embodiments;

FIG. 4 is another reflectance curve diagram of an anti-glare substrate to light in specific wavelengths, in accordance with some embodiments;

FIG. 5 is a reflectance curve diagram of an optical device to light in specific wavelengths, in a comparative example; and

FIG. 6 is a reflectance comparison table of different film layer structures to light.

### DETAILED DESCRIPTION

Technical solutions in some embodiments of the present disclosure will be described clearly and completely with reference to the accompanying drawings below. However, the described embodiments are merely some but not all embodiments of the present disclosure. All other embodiments obtained by those of ordinary skill in the art based on the embodiments provided in the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representation of the above terms does not necessarily refer to the same embodiment(s) or examples(s). In addition, the specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the features. In the description of the embodiments of the present disclosure, unless otherwise specified, the term “a plurality of/the plurality of” means two or more.

The phrase “one or more of A, B and C” includes the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the terms such as “about” or “approximately” includes a stated value and an average value within an acceptable deviation range of a specific value. The acceptable deviation range is determined by a person of ordinary skill in the art in view of the measurement in question and the error associated with the measurement of a particular quantity (i.e., limitations of the measurement system).

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

In the related art, in order to solve a problem that drivers are easily dazzled by strong light from the rear vehicle, two solutions are usually adopted.

One of the solutions is that a transflective film is adhered to a surface of a vehicle rearview mirror display (or a mirror glass plate with an aluminum (Al) film is additionally provided on the vehicle rearview mirror display), and then a blue film is adhered to the transflective film. On one hand, the blue film has poor wear resistance, which is easy to be worn; and bubbles are easily formed during adhering. On the other hand, two films (the transflective film and the blue film) are adhered to the surface of the vehicle rearview mirror display, so that light extraction efficiency will be reduced, and display ghosting will appear, which results in a poor quality of images displayed by the vehicle rearview mirror display.

It is found through research that, normally, a wavelength of visible light that may be perceived by human eyes is in a range from 400 nm to 780 nm. However, sensitivities of the human eyes to light of different wavelengths are different. Human eye has a highest perception efficiency to yellow-green light of a wavelength of 555 nm, while has a low perception efficiency to blue light. For example, under the same luminance, light in a wavelength band of 500 nm to 600 nm perceived by human eyes is brighter, and light in a wavelength band of 400 nm to 500 nm perceived by human eyes is darker. That is, the yellow-green light (the light in the wavelength band of 500 nm to 600 nm) is relatively sensitive light for human eyes, while blue-violet light (light in a wavelength band of 400 nm to 500 nm) is most adaptable light for human eyes. A brightness is visual reflection to luminance of light.

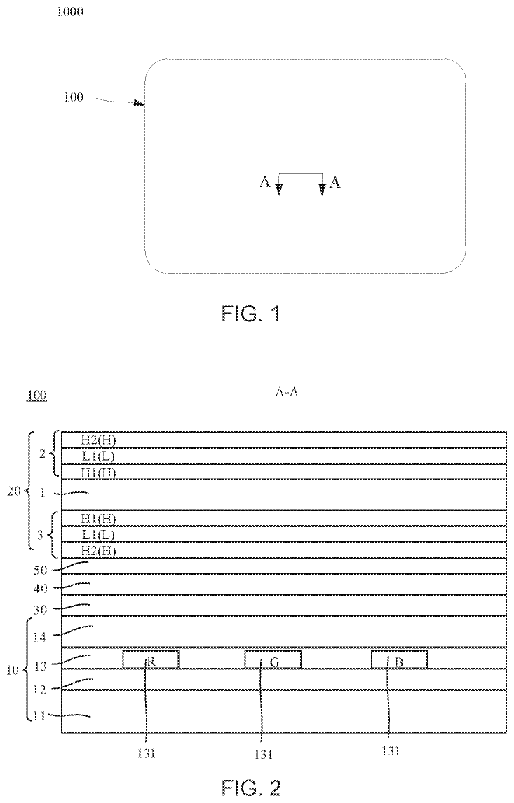

With reference to FIG. 1, some embodiments of the present disclosure provide a display device 1000. The display device 1000 may be any head-up display, such as a vehicular rearview display, a streaming media rearview mirror, a smart rearview mirror, a vehicle data recorder, or may be any product or component having a display function, such as a television, a monitor, a laptop, a tablet computer, a mobile phone, or a navigator.

The display device 1000 may be a liquid crystal display (LCD). The display device may also be an electroluminescent display device or a photoluminescent display device. In the case where the display device is the electroluminescent display device, the electroluminescent display device may be an organic light-emitting diode (OLED) display device or a quantum dot light-emitting diode (QLED) display device. In the case where the display device is the photoluminescent display device, the photoluminescent display device may be a quantum dot photoluminescent display device.

With reference to FIG. 2, the display device 1000 provided in the embodiments of the present disclosure includes a display module 100. The display module 100 includes a display panel 10 and an anti-glare substrate 20 that are stacked.

For example, in a case where the display device 1000 is the OLED display device, the display panel 10 includes a substrate 11, an array substrate 12, a light-emitting functional layer 13 and an encapsulation layer 14 that are stacked. The light-emitting functional layer 13 includes a plurality of sub-pixels 131. The sub-pixels 131 include red sub-pixels R, green sub-pixels G and blue sub-pixels B.

The display panel 10 has a light exit surface and a backlight surface. The light exit surface refers to a surface of the display panel 10 for displaying image information (an upper surface of the display panel 10 in FIG. 2). The backlight surface refers to a surface of the display panel 10 opposite to the light exit surface (a lower surface of the display panel 10 in FIG. 2). The anti-glare substrate 20 is disposed on a side of the light exit surface of the display panel 10.

With reference to FIG. 2, the anti-glare substrate 20 includes a base 1, a first laminated structure 2 and a second laminated structure 3. The first laminated structure 2 and the second laminated structure 3 are respectively disposed on opposite sides of the base 1. The first laminated structure 2 includes a plurality of high-refractive-index film layers H and at least one low-refractive-index film layer L, and the plurality of high-refractive-index film layers H and the at least one low-refractive-index film layer L included in the first laminated structure 2 are alternately arranged on a side of the base 1. The second laminated structure 3 includes a plurality of high-refractive-index film layers H and at least one low-refractive-index film layer L, and the plurality of high-refractive-index film layers H and the at least one low-refractive-index film layer L included in the second laminated structure 3 are alternately arranged on the other side of the base 1. In the first laminated structure 2, a film layer farthest from the base 1 and a film layer closest to the base 1 are both high-refractive-index film layers H. In the second laminated structure 3, a film layer farthest from the base 1 and a film layer closest to the base 1 are both high-refractive-index film layers H.

For example, with reference to FIG. 2, on either side of the base 1, in a direction perpendicular to and away from the base 1, the anti-glare substrate 20 includes a high-refractive-index film layer H, a low-refractive-index film layer L, another high-refractive-index film layer H, another low-refractive-index film layer L, . . . , and yet another high-refractive-index film layer H arranged in sequence. FIG. 2 only exemplarily illustrates two high-refractive-index film layers H and one low-refractive-index film layer L located on the side of the base 1, but the number of film layers may also be increased.

For the anti-glare substrate 20 included in the display module 100 provided in the embodiments of the present disclosure, when light is incident on the anti-glare substrate 20, the anti-glare substrate 20 has different transmittances and reflectances to light of different wavelengths. With the property of the anti-glare substrate 20 having different transmittances and reflectances to light of different wavelengths, the transmittance of the yellow-green light of the anti-glare substrate 20 may be greater than the transmittance of the blue-violet light of the anti-glare substrate 20 (the reflectance of the blue-violet light is greater than the reflectance of the yellow-green light), so that the proportion of the blue-violet light reflected by anti-glare substrate 20 is increased and the proportion of the yellow-green light reflected by anti-glare substrate 20 is reduced (reflecting the blue-violet is light as much as possible and reducing reflection of the yellow-green light), on a basis of a total reflectance (a reflectance of a full-wave band) of the anti-glare substrate 20 greater than 40%. Since sensitivity of human eyes to the blue-violet light is lower than sensitivity of human eyes to the yellow-green light, a degree and a possibility of dazzling drivers (human eyes) are reduced. Moreover, the total reflectance of the anti-glare substrate 20 is greater than 40%, which does not affect the driver's observation of road condition information behind the vehicle during the day.

In some embodiments, the number of film layers of the first laminated structure 2 and the number of film layers of the second laminated structure 3 are the same. That is, the number of high-refractive-index film layers H included in the first laminated structure 2 and the number of high-refractive-index film layers H includes in the second laminated structure 3 are the same; and the number of low-refractive-index film layers L included in the first laminated structure 2 and the number of low-refractive-index film layers L included in the second laminated structure 3 are the same.

In some embodiments, the first laminated structure 2 and the second laminated structure 3 are symmetrically arranged with respect to the base 1. That is, materials and thicknesses of a high-refractive-index film layer H of the first laminated structure 2 and a high-refractive-index film layer H of the second laminated structure 3 corresponding to each other are the same, and materials and thicknesses of a low-refractive-index film layer L of the first laminated structure 2 and a low-refractive-index film layer L of the second laminated structure 3 corresponding to each other are the same. The first laminated structure 2 and the second laminated structure 3 are symmetrically arranged with respect to the base 1, which is conducive to improving the reflectance of the anti-glare substrate 20, increasing the proportion of the blue-violet light reflected by the anti-glare substrate 20, and improving the anti-glare capability of the anti-glare substrate 20. In the direction perpendicular to and away from the base 1, the high-refractive-index film layers H included in each of the first laminated structure 2 and the second laminated structure 3 are sequentially numbered, and the low-refractive-index film layers L included in each of the first laminated structure 2 and the second laminated structure 3 are sequentially numbered. The phrase “corresponding to each other” refers to high-refractive-index film layers H with a same number in the first laminated structure 2 and the second laminated structure 3, and low-refractive-index film layers L with a same number in the first laminated structure 2 and the second laminated structure 3.

For example, the high-refractive-index film layers H and the low-refractive-index film layers L included in each of the first laminated structure 2 and the second laminated structure 3 are sequentially numbered as: a first high-refractive-index film layer H1, a first low-refractive-index film layer L1, a second high-refractive-index film layer H2, a second low-refractive-index film layer L2, . . . , an Nth high-refractive-index film layer HN, an Nth low-refractive-index film layer LN, and an (N+1)th high-refractive-index film layer H(N+1). An Mth high-refractive-index film layer HM included in the first laminated structure 2 corresponds to an Mth high-refractive-index film layer HM included in the second laminated structure 3, where M is a positive integer greater than or equal to 1 and less than or equal to (N+1). A Qth low-refractive-index film layer LQ included in the first laminated structure 2 corresponds to a Qth low-refractive-index film layer LQ included in the second laminated structure 3, where Q is a positive integer greater than or equal to 1 and less than or equal to N.

In some embodiments, a thickness of the high-refractive-index film layer H is in a range from 10 nm to 45 nm; and/or a thickness of the low-refractive-index film layer L is in a range from 80 nm to 120 nm. According to the verification of simulation experiments, in the case where the thickness of the high-refractive-index film layer H is in the range from 10 nm to 45 nm, and/or the thickness of the low-refractive-index film layer L is in the range from 80 nm to 120 nm, the reflectance of the full-wave band of the anti-glare substrate 20 is greater than 40%, and the reflectance of the blue-violet light is greater than the reflectance of the yellow-green light, which is beneficial to improving the anti-glare capability of the anti-glare substrate. For example, the thickness of the high-refractive-index film layer H may be 10 nm, 20 nm, 45 nm, etc., which will not be exemplified one by one here. The thickness of the low-refractive-index film layer L may be 80 nm, 100 nm, and 120 nm, etc., which will not be exemplified one by one here.

In some embodiments, a refractive index of the high-refractive-index film layer H to visible light is in a range from 2 to 2.5; and/or a refractive index of the low-refractive-index film layer L to visible light is in a range from 1.3 to 1.5. According to the verification of simulation experiments, in the case where the refractive index of the high-refractive-index film layer H to visible light is in the range from 2 to 2.5, and/or the refractive index of the low-refractive-index film layer L to visible light is in the range from 1.3 to 1.5, the reflectance of the full-wave band of the anti-glare substrate 20 is greater than 40%, and the reflectance of the blue-violet light is greater than the reflectance of the yellow-green light, which may reduce risk of dazzling the drivers. For example, the refractive index of the high-refractive-index film layer H to visible light may be 2, 2.3, 2.5, etc., which will not be exemplified one by one here. The refractive index of the low-refractive-index film layer to visible light may be 1.3, 1.35, 1.4, 1.5, etc., which will not be exemplified one by one here.

According to computer simulation analysis, in a case where the thickness of the high-refractive-index film layer H is in the range from 10 nm to 45, the refractive index of the high-refractive-index film layer H to visible light is in the range from 2 to 2.5, the thickness of the low-refractive-index film layer L is in the range from 80 nm to 120 nm, and the refractive index of the low-refractive-index film layer to visible light is in the range from 1.3 to 1.5, the reflectance of the anti-glare substrate 20 to the blue-violet light is greater than the reflectance of the anti-glare substrate 20 to the yellow-green light, which may reduce the risk of dazzling the drivers.

In some embodiments, a material of the high-refractive-index film layer H includes one or more of titanium dioxide, niobium pentoxide and tantalum pentoxide; and/or a material of the low-refractive-index film layer L includes silicon oxide and/or magnesium fluoride.

In some embodiments, the base 1 is a rigid base or a flexible base. For example, the rigid base may be a glass base. The flexible base may be a resin base. In the case where the base 1 is the rigid base, the anti-glare substrate 20 has high structural strength and high structural stability, and is not easily deformed. In the case where the base 1 is the flexible base, the anti-glare substrate 20 may be deformed to a certain extent, which is conducive to bonding of the anti-glare substrate 20 and the display panel 10. For example, the display panel 10 included in the display module 100 may be a rigid display panel or a flexible display panel. In the case where the display panel 10 is the rigid display panel, the base 1 may be the rigid base or the flexible base. In the case where the display panel 10 is the flexible display panel, the base 1 may be the flexible base.

In some embodiments, with reference to FIG. 2, the first laminated structure 2 and the second laminated structure 3 each include three film layers. In the direction perpendicular to and away from the base 1, the three film layers are sequentially a first high-refractive-index film layer H1, a first low-refractive-index film layer L1 and a second high-refractive-index film layer H2. As thicknesses of film layers included in the first laminated structure 2 and the second laminated structure 3 increases, the reflectance of the anti-glare substrate 20 to light of various wavelengths gradually increases, and the transmittance of the anti-glare substrate 20 to the light of various wavelengths gradually decreases. The first laminated structure 2 and the second laminated structure 3 each include the three film layers, which may reduce influence on the light extraction efficiency of the display module 100 caused by the anti-glare substrate 20.

In the case where the first laminated structure 2 and the second laminated structure 3 each include the three film layers, a ratio of a thickness of the first high-refractive-index film layer to a thickness of the second high-refractive-index film layer is in a range from 2/7 to 417, and a ratio of the thickness of the first high-refractive-index film layer to a thickness of the first low-refractive-index film layer is in a range from 1/10 to 1/5. According to verification of simulation experiments, in the case where the ratio of the thickness of the first high-refractive-index film layer to the thickness of the second high-refractive-index film layer is in the range from 2/7 to 4/7, and the ratio of the thickness of the first high-refractive-index film layer to the thickness of the first low-refractive-index film layer is in the range from 1/10 to 1/5, the reflectance of the anti-glare substrate 20 to the full-wave band is greater than 40%, and the reflectance of the anti-glare substrate 20 to the blue-violet light is greater than the reflectance of the anti-glare substrate 20 to the yellow-green light, which may reduce the risk of dazzling the drivers.

For example, the first high-refractive-index film layer H1 is made of titanium dioxide (TiO₂), and a thickness thereof is in a range from about 13 nm to about 17 nm (about (15±2) nm); the first low-refractive-index film layer L1 is made of silicon dioxide (SiO₂), and a thickness thereof is in a range from about 98 nm to about 102 nm (about (100±2) nm); and the second high-refractive-index film layer H2 is made of titanium dioxide (TiO₂), and a thickness thereof is in a range from about 33 nm to about 37 nm (about (35±2) nm). The “±2” refers to, based on a selected thickness value of each film layer, fluctuating values within a reasonable range due to manufacturing accuracy and measurement error. Of course, fluctuating values may also be “±1”, or “±5”, etc., which will not be exemplified one by one here.

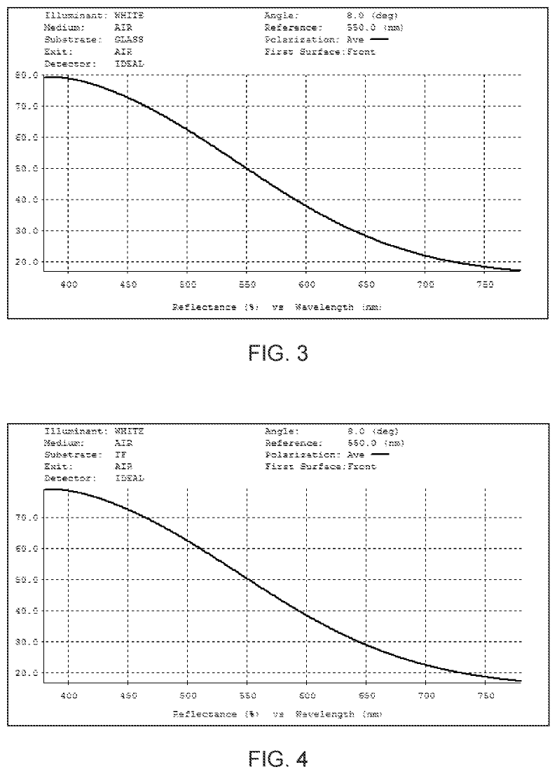

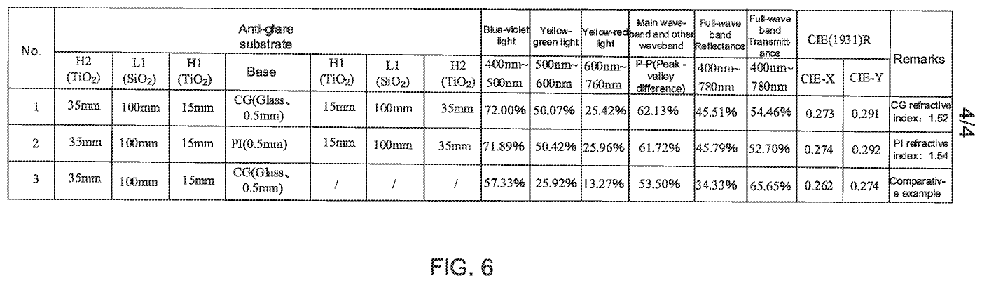

With reference to FIG. 3, FIG. 3 is a reflectance curve diagram of the anti-glare substrate 20 to light of specific wavelengths, in a case where the base 1 is the rigid base (the glass base) with a thickness of 0.5 mm and a refractive index of 1.52, and the film layers included in the anti-glare substrate 20 have parameters (including thicknesses and materials) as shown in a first row in FIG. 6 (a row with No. 1, in which the first high-refractive-index film layer H1 is made of titanium dioxide (TiO₂) with a thickness of 15 nm, the first low-refractive-index film layer L1 is made of silicon dioxide (SiO₂) with a thickness of 100 nm, and the second high-refractive-index film layer H2 is made of titanium dioxide (TiO₂) with a thickness of 35 nm). It can be seen from the diagram that: the reflectance of the anti-glare substrate 20 to the blue-violet light (light of a wavelength from 400 nm to 500 nm) is greater than the reflectance of the anti-glare substrate 20 to the yellow-green light (light of a wavelength from 500 nm to 600 nm). Moreover, it can be seen form FIG. 6 that, the reflectance of the anti-glare substrate 20 to the blue-violet light is about 72.00%, and the reflectance of the anti-glare substrate 20 to the yellow-green light is about 50.07%. Thus, the reflectance of the anti-glare substrate 20 to the blue-violet light is greater than the reflectance of the anti-glare substrate 20 to the yellow-green light, which may reduce the degree and the possibility of dazzling the drivers (human eyes), and improve the driving safety of the drivers at night. Moreover, the reflectance of the anti-glare substrate to the full-wave band (light of a wavelength from 400 nm to 780 nm) is about 45.51%, and thus it may meet Motor vehicles—Rearview mirrors—Requirements of performance and installation (GB 15084-2006) of the national standard of the People's Republic of China, which stipulates that a reflectance of an interior rearview mirror of a motor vehicle should be greater than or equal to 40% (Z 40%) during the day. A transmittance of the anti-glare substrate 20 to the full-wave band is about 54.46%, so that the light extraction efficiency of the display panel 10 may meet requirements of displaying image information.

With reference to FIG. 4, FIG. 4 is a reflectance curve diagram of the anti-glare substrate 20 to light of specific wavelengths, in a case where the base 1 is the flexible base (a polyimide (PI) base) with a thickness of 0.5 mm and a refractive index of 1.54, and the film layers included in the anti-glare substrate 20 have parameters (including thicknesses and materials) as shown in a second row in FIG. 6 (a row with No. 2, in which the first high-refractive-index film layer H1 is made of titanium dioxide (TiO₂) with a thickness of 15 nm, the first low-refractive-index film layer L1 is made of silicon dioxide (SiO₂) with a thickness of 100 nm, and the second high-refractive-index film layer H2 is made of titanium dioxide (TiO₂) with a thickness of 35 nm). It can be seen from the diagram that: the reflectance of the anti-glare substrate 20 to the blue-violet light (light of the wavelength from 400 nm to 500 nm) is greater than the reflectance of the anti-glare substrate 20 to the yellow-green light (light of the wavelength from 500 nm to 600 nm). Moreover, it can be seen from FIG. 6 that, the reflectance of the anti-glare substrate 20 to the blue-violet light is about 71.89%, and the reflectance of the anti-glare substrate 20 to the yellow-green light is about 50.42%. Thus, the reflectance of the anti-glare substrate to the blue-violet light is greater than the reflectance of the anti-glare substrate 20 to the yellow-green light, which may reduce the degree and the possibility of dazzling drivers (human eyes), and improve the driving safety of the drivers at night. Moreover, the reflectance of the anti-glare substrate 20 to the full-wave band (light of the wavelength from 400 nm to 780 nm) is about 45.79%, and thus it may meet Motor vehicles—Rearview mirrors—Requirements of performance and installation (GB 15084-2006) of the national standard of the People's Republic of China, which stipulates that the reflectance of the interior rearview mirror of the motor vehicle should be greater than or equal to 40% (≥40%) during the day. A transmittance of the anti-glare substrate 20 to the full-wave band is about 52.70%, so that the light extraction efficiency of the display panel 10 may meet the requirements of displaying image information.

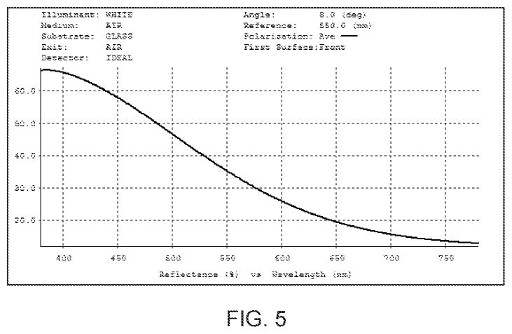

Embodiments of the present disclosure also provide a comparative example. With reference to FIG. 5, FIG. 5 is a reflectance curve diagram of an optical device to light of specific wavelengths, in a case where a base 1 is a rigid base (a glass base) with a thickness of 0.5 mm and a refractive index of 1.52, high-refractive-index film layers H and a low-refractive-index film layer L are alternately provided on only one side (a single side) of the base 1, and materials and thicknesses of the film layers are as shown in a third row in FIG. 6 (a row with No. 3, in which a first high-refractive-index film layer H1 is made of titanium dioxide (TiO₂) with a thickness of 15 nm, a first low-refractive-index film layer L1 is made of silicon dioxide (SiO₂) with a thickness of 100 nm, and a second high-refractive-index film layer H2 is made of titanium dioxide (TiO₂) with a thickness of 35 nm). By comparing FIG. 3 and FIG. 5, and in combination with FIG. 6, it can be seen that, for a case where only one side of the base 1 is provided with the laminated structure thereon, a reflectance of the optical device to the full-wave band is less than 40%, which does not meet the national standard. The anti-glare substrate 20 provided in the embodiments of the present disclosure may, on a premise of meeting the national standard (a reflectance of visible light during the day being greater than or equal to 40% (≥40%)), increase the reflective proportion of the blue-violet light and reduce the reflective proportion of the yellow-green light, which may reduce the degree and the possibility of dazzling the drivers (human eyes), and improve the driving safety of the drivers at night.

Some embodiments of the present disclosure provide a display module 100. The display module 100 includes the display panel 10 and an anti-glare substrate 20. The display panel 10 has the light exit surface and the backlight surface. The anti-glare substrate 20 is disposed on a side of the light exit surface of the display panel 10.

With reference to FIG. 2, the anti-glare substrate 20 includes a base 1 and two laminated structures (a first laminated structure 2 and a second laminated structure 3). The two laminated structures are respectively disposed on opposite sides of the base 1. Each laminated structure includes a plurality of high-refractive-index film layers H and at least one low-refractive-index film layer L that are alternately arranged on the base 1, and in the laminated structure, a film layer farthest from the base 1 and a film layer closest to the base 1 are both the high-refractive-index film layers H. A thickness of each high-refractive-index film layer is in a range from 10 nm to 45 nm (10 nm-45 nm), and a refractive index of the high-refractive-index film layer H to visible light is in a range from 2 to 2.5; and/or a thickness of each low-refractive-index film layer L is in a range from 80 nm to 120 nm, and a refractive index of the low-refractive-index film layer to visible light is in a range from 1.3 to 1.5.

In the display module 100 provided in the embodiments of the present disclosure, the anti-glare substrate 20 is disposed on the side of the light exit surface of the display panel 10. The reflectance of the anti-glare substrate 20 to the blue-violet light is greater than the reflectance of the anti-glare substrate 20 to the yellow-green light. The proportion of the blue-violet light reflected by anti-glare substrate 20 is greater than the proportion of the yellow-green light reflected by anti-glare substrate 20. Since the sensitivity of human eyes to the blue-violet light is lower than the sensitivity of human eyes to the yellow-green light, on the premise of the total reflectance of the anti-glare substrate 20 greater than 40%, it may be possible to reduce the degree and the possibility of dazzling the drivers (human eyes), and improve driving safety of the drivers at night.

With reference to FIG. 1, some embodiments of the present disclosure provide a display device 1000, which includes the display module 100 described in any one of the above embodiments. According to the same structure as the display module 100, the display device 1000 may, on the premise of the total reflectance of the anti-glare substrate greater than 40%, reduce the degree and the possibility of dazzling the drivers (human eyes), and improve the driving safety of the drivers at night.

In some embodiments, with reference to FIG. 2, the display device 1000 further includes an adhesive layer 30, a circular polarizer 40 and an optical adhesive 50. The adhesive layer 30 is disposed on the light exit surface of the display panel 10. The circular polarizer 40 is disposed on a side of the adhesive layer 30 away from the display panel 10, and the adhesive layer 30 is used for bonding the display panel 10 to the circular polarizer 40. The optical adhesive 50 is disposed between the circular polarizer 40 and the anti-glare substrate 20, and used for bonding the circular polarizer 40 to the anti-glare substrate 20. The circular polarizer 40 may reduce reflection on the surface of the display panel 10, which prevents color separation phenomenon from occurring on the surface of the display panel 10.

The foregoing descriptions are merely specific implementations of the present disclosure. However, the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel having a light exit surface and a backlight surface; and
an anti-glare substrate disposed on a side of the light exit surface of the display panel, wherein the anti-glare substrate includes a base, a first laminated structure and a second laminated structure, and the first laminated structure and the second laminated structure are respectively disposed on opposite sides of the base, wherein—
the first laminated structure includes a plurality of high-refractive-index film layers and at least one low-refractive-index film layer, and the plurality of high-refractive-index film layers and the at least one low-refractive-index film layer included in the first laminated structure are alternately arranged on a side of the base; and the second laminated structure includes a plurality of high-refractive-index film layers and at least one low-refractive-index film layer, and the plurality of high-refractive-index film layers and the at least one low-refractive-index film layer included in the second laminated structure are alternately arranged on another side of the base, wherein in the first laminated structure, a film layer farthest from the base and a film layer closest to the base are both high-refractive-index film layers; and in the second laminated structure, a film layer farthest from the base and a film layer closest to the base are both high-refractive-index film layers.

2. The display module according to claim 1, wherein the number of film layers of the first laminated structure and the number of film layers of the second laminated structure are same.

3. The display module according to claim 1, wherein
a thickness of a high-refractive-index film layer of the first laminated structure and a thickness of a high-refractive-index film layer of the second laminated structure are in a range from 10 nm to 45 nm; and/or
a thickness of a low-refractive-index film layer of the first laminated structure and a thickness of a low-refractive-index film layer of the second laminated structure are in a range from 80 nm to 120 nm.

4. The display module according to claim 1, wherein
a refractive index of a high-refractive-index film layer of the first laminated structure to visible light and a refractive index of a high-refractive-index film layer of the second laminated structure to visible light are in a range from 2 to 2.5, and/or
a refractive index of a low-refractive-index film layer of the first laminated structure to visible light and a refractive index of a low-refractive-index film layer of the second laminated structure to visible light are in a range from 1.3 to 1.5.

5. The display module according to claim 1, wherein
a material of a high-refractive-index film layer of the first laminated structure and a material of a high-refractive-index film layer of the second laminated structure includes one or more of titanium dioxide, niobium pentoxide and tantalum pentoxide; and/or
a material of a low-refractive-index film layer of the first laminated structure and a material of a low-refractive-index film layer of the second laminated structure includes silicon dioxide and/or magnesium fluoride.

6. The display module according to claim 1, wherein the first laminated structure and the second laminated structure each include three film layers; the three film layers are sequentially a first high-refractive-index film layer, a first low-refractive-index film layer and a second high-refractive-index film layer in a direction perpendicular to and away from the base.

7. The display module according to claim 6, wherein a ratio of a thickness of the first high-refractive-index film layer to a thickness of the second high-refractive-index film layer is in a range from 2/7 to 4/7; and a ratio of the thickness of the first high-refractive-index film layer to a thickness of the first low-refractive-index film layer is in a range from 1/10 to 1/5.

8. The display module according to claim 7, wherein the first high-refractive-index film layer is made of titanium dioxide, and a thickness thereof is in a range from 13 nm to 17; and the first low-refractive-index film layer is made of silicon dioxide, and a thickness thereof is in a range from 98 nm to 102 nm; and the second high-refractive-index film layer is made of titanium dioxide, and a thickness thereof is in a range from 33 nm to 37 nm.

9. A display module, comprising:
a display panel having a light exit surface and a backlight surface; and
an anti-glare substrate disposed on a side of the light exit surface of the display panel, wherein the anti-glare substrate includes a base and two laminated structures that are respectively disposed on opposite sides of the base; each laminated structure includes a plurality of high-refractive-index film layers and at least one low-refractive-index film layer, and the plurality of high-refractive-index film layers and the at least one low-refractive-index film layer are alternately arranged on the base; and in the laminated structure, a film layer farthest from the base and a film layer closest to the base are both high-refractive-index film layers, wherein
a thickness of each high-refractive-index film layer is in a range from 10 nm to 45 nm, and a refractive index of the high-refractive-index film layer to visible light is in a range from 2 to 2.5; and/or
a thickness of each low-refractive-index film layer is in a range from 80 nm to 120 nm, and a refractive index of the low-refractive-index film layer to visible light is in a range from 1.3 to 1.5.

10. A display device, comprising:
the display module according to claim 1.

11. The display device according to claim 10, further comprising:
a circular polarizer disposed between the display panel and the anti-glare substrate of the display module; and
an optical adhesive disposed between the circular polarizer and the anti-glare substrate to bond the circular polarizer to the anti-glare substrate.

12. The display device according to claim 11, further comprising:
an adhesive layer disposed between the display panel and the circular polarizer to bond the display panel to the circular polarizer.

13. A display device, comprising:
the display module according to claim 9.

14. The display device according to claim 13, further comprising:
a circular polarizer disposed between the display panel and the anti-glare substrate of the display module; and
an optical adhesive disposed between the circular polarizer and the anti-glare substrate to bond the circular polarizer to the anti-glare substrate.

15. The display device according to claim 14, further comprising:
an adhesive layer disposed between the display panel and the circular polarizer to bond the display panel to the circular polarizer.

16. The display module according to claim 2, wherein
a thickness of a high-refractive-index film layer of the first laminated structure and a thickness of a high-refractive-index film layer of the second laminated structure are in a range from 10 nm to 45 nm; and/or
a thickness of a low-refractive-index film layer of the first laminated structure and a thickness of a low-refractive-index film layer of the second laminated structure are in a range from 80 nm to 120 nm.

17. The display module according to claim 2, wherein
a refractive index of a high-refractive-index film layer of the first laminated structure to visible light and a refractive index of a high-refractive-index film layer of the second laminated structure to visible light are in a range from 2 to 2.5, and/or
a refractive index of a low-refractive-index film layer of the first laminated structure to visible light and a refractive index of a low-refractive-index film layer of the second laminated structure to visible light are in a range from 1.3 to 1.5.

18. The display module according to claim 3, wherein
a refractive index of the high-refractive-index film layer of the first laminated structure to visible light and a refractive index of the high-refractive-index film layer of the second laminated structure to visible light are in a range from 2 to 2.5, and/or
a refractive index of the low-refractive-index film layer of the first laminated structure to visible light and a refractive index of the low-refractive-index film layer of the second laminated structure to visible light are in a range from 1.3 to 1.5.

19. The display module according to claim 2, wherein
a material of a high-refractive-index film layer of the first laminated structure and a material of a high-refractive-index film layer of the second laminated structure include one or more of titanium dioxide, niobium pentoxide and tantalum pentoxide; and/or
a material of a low-refractive-index film layer of the first laminated structure and a material of a low-refractive-index film layer of the second laminated structure include silicon dioxide and/or magnesium fluoride.

20. The display module according to claim 3, wherein
a material of the high-refractive-index film layer of the first laminated structure and a material of the high-refractive-index film layer of the second laminated structure include one or more of titanium dioxide, niobium pentoxide and tantalum pentoxide; and/or
a material of the low-refractive-index film layer of the first laminated structure and a material of the low-refractive-index film layer of the second laminated structure include silicon dioxide and/or magnesium fluoride.
